(19) United States
(12) Patent Application Publication
(10) Pub. No.: US 2026/0127327 A1
(43) Pub. Date: May 7, 2026

(54) Quantum Computing Fractal Compression And Decentralized Computing For Predictive Physics Simulation

(71) Applicant: Essam Abadir, Lancaster, PA (US)

(72) Inventor: Essam Abadir, Lancaster, PA (US)

(21) Appl. No.: 18/939,219

(22) Filed: Nov. 6, 2024

(51) Int. Cl. G06F 30/17

(52) U.S. Cl. CPC G06F 30/17

(57) ABSTRACT

The disclosure relates to methods for predictive physics compression (PPC) for efficient simulations and calculation leveraging techniques described as fractal compression. Unlike traditional calculus-based methods relying on differential equations and related numerical methods, embodiments of the disclosure are directed towards representation and calculation of physical systems as hierarchical frames within a universal grid, where each frame encapsulates properties such as position and velocity. The simulations and calculations progress in discrete time steps recursively traversing the frame hierarchy. Each tick involves actions such as incorporating the previous frame relation's displacement, detecting collisions, applying stochastic movement and attractive force transforms, and limiting displacement based on defined constraints. Embodiments of the disclosure may be implemented on a single device or distributed across a network, with a coordination server distributing frames to client devices for parallel processing.

### TECHNICAL FIELD

The present invention relates generally to physics simulations and, more particularly, but not exclusively to employing fractal approaches for efficient computational algorithms and computing architectures to the calculation of physical phenomena.

### BACKGROUND

Physics simulations involve predicting the future state, or time evolution, of a physical system. One can think of physics simulations as creating “pictures” of the future, similar to how computer-generated graphics depict the swirling of smoke over a fire or the way shattered glass produces tiny reflections in its shards. As covered in the popular treatment, Chaos: Making A New Science, by James Gleick, “[some scientists] say the twentieth century will be remembered for three things: Relativity, Quantum Mechanics, and Chaos” and envisioning physics as pictures of the future is a technique largely attributable to innovations by Edward Lorenz and his weather simulations. Unfortunately, till this day, our ability to achieve breakthroughs like cold fusion, superconductors, and even cancer cures is fundamentally rate limited by our ability to compute these three great areas as one thing and, therefore, the speed at which we can create these “pictures” of how quantum particles, atoms, molecules, and celestial bodies interact. Reducing or “compressing” calculations while limiting errors is crucial to enabling such innovations. Despite many advances in computation and our understanding of physics, as just one example, simulations of fusion reactions require supercomputers with millions of CPU or GPU cores, and even then, our ability to accurately simulate real-world phenomena remains limited.

Quantum Mechanics and General Relativity are based on continuous concepts of space-time, where infinite amounts of computing power are needed to perfectly solve even the simplest systems. This is because, in the mathematical formulations of these theories, there are forces with infinite reach, where every particle can simultaneously influence every other particle. Computing the future states of a real-world physical system based on a continuous space-time requires the continuous mathematics of calculus and non-linear differential equations. This challenge was initially outlined by Henri Poincaré in his work on the Three-Body Problem, which gave birth to the field of Chaos Theory. We now know that the Three-Body Problem, and the more general N-Body Problem, are not solvable in closed form in a continuous space-time model, and perfectly predicting the future state of such systems is computationally intractable. Since there is currently no such thing as a “continuous supercomputer,” we instead use digital computers to simulate physical systems. In computer science, the number of operations required to perform a calculation is characterized by the “computational complexity” of an algorithm using Big O notation. For example, if a particle physics simulation with N particles is constrained such that each particle interacts with only a fixed number of other particles in each time step, then the computational complexity is O(N), which is manageable with modern computing resources. However, if each particle influences the calculation of every other particle simultaneously (without being limited to pairwise interactions), the problem becomes exponentially complex, with computational complexity on the order of O(N_{N}).

As an illustrative example, for an O(N) problem where N=1 billion particles, it is feasible to model on modern multi-core processors that perform billions of calculations per second per core. On the other hand, if Nis only 100 and the problem is O(N^{N}), then the number of calculations required is 100¹⁰⁰ (a 1 followed by 200 zeros), which is beyond the capability not only of current computers, but any digital computer that could ever be invented.

Rather than give up on using computers, physicists often employ numerical methods that introduce approximations to make N-Body problems computationally tractable. By making simplifying assumptions—such as limiting interactions to pairwise effects and neglecting higher-order simultaneous influences—they reduce the computational complexity, albeit at the cost of introducing errors. For instance, if we limit the interactions to pairwise effects without considering simultaneous changes causing recalculations, the complexity becomes O(N²). This is computable for smaller systems with, say, 10,000 particles, but becomes unmanageable as N grows larger. Further approximations can reduce the complexity to O(N log N) or even O(N), but in a continuous space-time model, these approximations introduce additional errors, which may not be acceptable for certain applications. It is these errors that limit our ability to achieve advancements in areas such as cold fusion, new materials, and novel medicines.

Mathematics, composed of symbols and operators, serves as the language for expressing physical theories. However, different theories of physics utilize different subsets of mathematics, making it confusing and overly broad to discuss the entire field as it relates to any particular approach to physics prediction and simulation. Accordingly, for definitional purposes, the related predictive mathematical techniques for a particular theory of physics are herein referred to as Physics Computation Languages (PCLs). Calculus and statistical mechanics are some of the primary PCLs in use today, and we can discuss them through the lens of compressions, which reduce the number of calculations necessary to predict the future. For example, quantum mechanics and calculus are PCLs in which Schrödinger's wave equation is used to model a hydrogen atom, thereby reducing the computation necessary to model the physics of a proton and electron over a short period of time. Still, as discussed previously, for elements more complex than hydrogen, with many subatomic particles, the computations grow so rapidly that even with the computational compression provided by the Schrödinger equation, the system becomes uncomputable.

Whether physics prediction is compressible is an open question and has been debated in many forms. As a sweeping oversimplification, the argument rests on whether forces have infinite reach because the universe is continuous, or whether forces have finite reach because the universe is discrete. On one side, the argument for infinite reach and non-compressibility is premised on a continuum assumption (a continuous space-time) and the fact that continuous equations cannot be perfectly accurately represented on digital computers. Digital computers, with their discrete 1's and 0's, assume a discontinuum (a discrete grid). As further elaborated by Sabine Hossenfelder in A No-go Theorem for Poincaré-Invariant Networks, the specific problem of using a discrete PCL is that there is no known discrete algorithm which preserves Lorentz invariance, although, as she has pointed out with causal sets, it is possible that such an algorithm could exist. It would be a fitting development if Edward Lorenz's Chaos were to be used to solve the problem of Relativity and Hendrik Lorentz′ invariance.

On the other side is a growing amount of evidence for compressibility. For example, the holographic principle, which posits that the information in a larger volume of space can be encoded onto the lesser area of its surface (i.e., compressed); this has been realized concretely in the theory of Anti-de Sitter space/Conformal Field Theory correspondence (AdS/CFT). Interestingly, AdS/CFT displays another important clue for compressibility in the form of “scale invariance,” where the holographic principle is evident at very large scales like black holes and very small scales like quantum fields. This self-similarity is important to note because, as will be discussed later, fractals are a mathematical form of self-similarity and are used in some compression algorithms.

Additionally, some say that one of the closes ideas to a theory of everything is the “principle of least action” it's like the universe is “lazy” and always chooses the most efficient way to evolve by “computing” the path of least action. The efficiency inherent in computing least action is a form of compression because it reduces the number of calculations necessary to predict the future.

In the computational industry, compression is most often discussed with respect to image and video data. It is helpful to differentiate compression into two classes—compressions which reverse engineer an existing image (herein REC), and compressions which predict a future image (herein “predictive physics compression” or PPC). For example, compressing an HD video is a REC compression because the video already exists and the compression is used to store the video more efficiently. In contrast, CGI for producing the visual effects in a movie and physics engines in video games are PPC compression because the video does not yet exist and the compression is used to reduce the number of calculations necessary to predict the future state of the video.

REC-type compression is the more well-known and developed field and is dominated by discrete cosine transform (DCT) techniques such as those in the H.264 video compression codec. The discrete cosine-based DCT is principally derived from the broader mathematical concept of the continuous Fourier transforms, which allow for complete reconstruction of calculus functions using a linear combination of cosine and sine functions. Note the self-similarity inherent in the Fourier transform, whose compressive technique is that any state of a system (an image) can be represented by a linear combination of wave graphs.

By contrast, the realm of PPC, which aims to predict future states at each time step, is dominated by a class of “numerical methods” such as ordinary differential equation (ODE) solvers like Runge-Kutta. Essentially, ODEs and their partial differential equation cousins are the calculus formulae that encapsulate the current theories of physics. For PPC purposes, practical alternatives to ODE solvers would need to address the N-Body problem in the context of Chaos and do so without reliance on calculus formulae. Instead ODE solver alternative would require “emergent physics,” that is, they would require an algorithm that has no knowledge of physics equations and from which physics behaviors would “emerge” on their own. Presently, there are no algorithms known in the art which display emergent behavior complying with observed physics, and accordingly, alternatives to ODE solvers are not well known or developed.

Fractals in the context of Chaos Theory are geometric patterns, built algorithmically, that exhibit self-similarity and emergent behaviors (not necessarily complying with observed physics). They are often generated by repeating simple processes, leading to intricate patterns that can be infinitely detailed. Fractals look the same at various scales, and from their repetition, complex behaviors emerge on their own. Examples of fractals include the Mandelbrot set and natural forms like coastlines or snowflakes. Fractals, like Edward Lorenz' strange attractors, which are tightly connected, but not one and the same, with Chaos Theory (also known as non-linear dynamics)—out of chaos these fractals give rise to emergent patterns. Just as fractals are tightly connected with chaos, so too is chaos tightly connected with the non-linear dynamic system we otherwise call physics.

Fractals are relevant to compression because they can describe complex images using simple, repetitive mathematical rules and have been used in limited fashions in both REC and PPC. In REC, fractal compression works by reverse engineering an image or pattern in order to decompose it into shapes formed by fractals. The process of fractal reverse engineering compression (or “FREC”) is one of finding self-similar patterns in an image and encoding these patterns with transformations (like scaling, rotation, and translation) instead of storing pixel-by-pixel data. This can result in significant compression ratios, particularly for images with repetitive or self-similar features.

FREC typically employs a fragmented geometric shape that may be subsequently divided into a plurality of parts, each of which at least approximately represents a reduced-size copy of the original—a concept called self-similarity. However, unless the underlying physical structure is formed according to some fractal set of rules, FREC is a lossy image compression approach in that the resulting output of the compression or encoding is but an approximation of the original, having lost some amount of non-redundant material in the compression. Thus, FREC is often used where the original image includes potentially self-similar components. One example of a FREC process is described in

U.S. Pat. No. 5,065,447 (herein, “the '447 Patent”) entitled Method and Apparatus for Processing Digital Data, issued on Nov. 12, 1991 to Barnsley et al., which is incorporated herein by reference in its entirety. Briefly, the fractal encoding disclosed in the '447 Patent iterates a block matching process to achieve improved compression or encoding results based on a number of iterations performed. However, as disclosed in U.S. Pat. No. 9,344,735 B2 entitled Progressive Shape Based Encoding of Video Content Within a Compression Environment, issued to Essam Ernest Abadir on May 17, 2016, which is incorporated herein by reference in its entirety (herein, “the '735 Patent”), such iterated function systems (IFS) can be very computationally intense. They are necessitated when an image does not have a known underlying fractal pattern from which the image can be generated given a small number of starting parameters and repeated application of the drawing pattern.

With regard to PPC, fractal compression of a sort is utilized to limited extent in game physics engines and CGI rendering, such as the Unreal Chaos Physics Engine used in Fortnite. In these applications, the physics engine must predict the future state of a system (e.g., the position of objects, the behavior of fluids) based on the current state and the laws of physics. While the Unreal Chaos engine uses fractals to a very limited extent, it is instructive in its existence. With regard to both FREC and PPC, a number of technologies are known in the art which can help speed the calculations necessary for transforms, and include, but are not limited to, numerical linear algebra (NLA), multi-threading, and GPUs. These technologies can optimize the process of fractal compression in a number of ways, including, but not limited to:
1. Parallel Search for Self-Similarity: CPU's, GPUs, cores, and threads can be used to parallelize the search for self-similar blocks across the image, significantly speeding up this phase by assigning different portions of the image to different threads. This allows multiple comparisons to occur simultaneously.
2. Transformation Calculations: NLA techniques can reduce the number of mathematical operations necessary to perform a transform calculation and achieve the same result. With the use of parallelism such as multi-threading, applying NLA transformations (scaling, rotation, etc.) to image blocks can be done concurrently across many cores, allowing calculation of these vector operations more efficiently and in parallel.

The compression ratios achievable with fractal compression could potentially far outstrip those achievable with other techniques. Additionally, the self-similar nature of fractals is amenable to parallelization and encapsulation of calculations that are potentially synergistic with multi-threading, GPUs, and NLA. While these properties of fractals are highly desirable for compression, the underlying fractal pattern of an image is rarely known. For this reason, FREC is rarely used for image or video compression, and instead DCT-based algorithms like H.264 dominate the field. However, the potential for fractal compression to be used in a predictive manner is a largely unexplored area of research.

In applications like PPC rendering, quantum computers might allow for far more detailed simulations of environments (e.g., realistic smoke, fire, or water) with reduced latency and better memory handling, making it possible to simulate millions of particles or deformable objects in real time.

One of the limitations of classical physics engines is their inability to accurately simulate quantum-level phenomena where there are not just a few particles but an essentially uncountable amount (e.g., electron interactions, molecular behaviors). In real-world physics modeling, classical computers struggle with simulating quantum systems due to the exponential growth of state spaces. For instance, molecular dynamics simulations in areas like drug discovery, material science, and even quantum field simulations could become significantly more efficient on quantum computers.

As an alternative to viable digital algorithmic compression that would make accurate physics simulations feasible on digital computers, it is thought that new physical quantum computing architectures might be able to perform the exponentially more computations necessary for physics prediction. Such physical quantum computing architectures are highly speculative as to whether they can even be built, despite many billions of dollars that have been invested for this purpose.

More efficient and accurate ways to do PPC are highly desirable in order to achieve potential humanity-benefiting breakthroughs like cold fusion or other currently unconceived technological advances. Predicting future states of a physical system is computationally exponentially more complex than reverse engineering present states and would require significantly higher compression ratios than REC. An alternative to ODE solvers which displays a very high rate of compression without loss of accuracy would be highly desirable. Fractals are discrete algorithms whose compression is derived from self-similarity and recursive application of simple rules. While fractals have been used to a limited extent in REC and PPC, there is neither a fractal nor a discrete algorithm known in the art which displays the emergent behavior of our known laws of physics. Therefore, it is with respect to these considerations and others that the present invention has been made.

### BRIEF DESCRIPTION OF THE DRAWINGS

FIG. 1 shows an illustrative distributed operating environment.

FIG. 2 shows an illustrative client computing device.

FIG. 3 shows an illustrative network device.

FIG. 4 shows a distributed calculation environment.

FIG. 5 shows a single-threaded, single-processor pass of the PPC algorithm.

FIG. 6 shows a distributed computation in a compression environment.

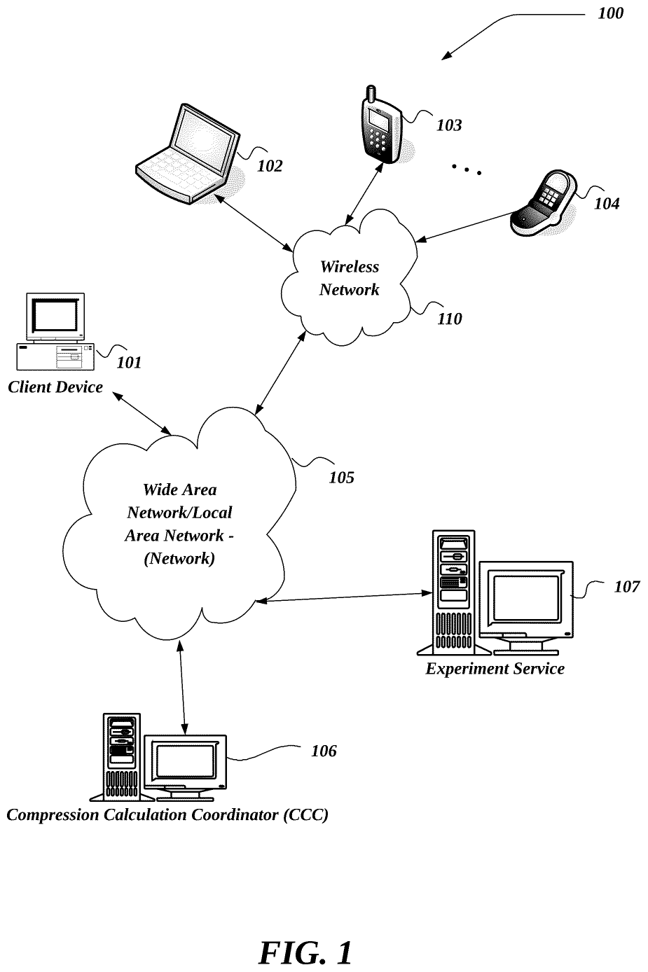

### FIG. 1. ILLUSTRATIVE DISTRIBUTED OPERATING ENVIRONMENT

FIG. 1 depicts an illustrative distributed computing operating environment for one embodiment of the invention. The environment includes a network (which can be a combination of LANs, WANs, and the Internet), a wireless network, a Compression Calculation Coordination (CCC) server, client devices, and an experiment service. The client devices can be any computational device, such as personal computers, laptops, tablets, or smartphones. The experiment service provides access to physics experiments, potentially using the Predictive Physics Compression (PPC) algorithm described herein. The CCC server plays a role in coordinating distributed computations. The client devices interact with the experiment service and the CCC server over the network and wireless network. They can request experiments, receive experiment data, and contribute to distributed computations. The architecture allows for flexibility in terms of the computational load distribution, with the possibility of both centralized and distributed processing.

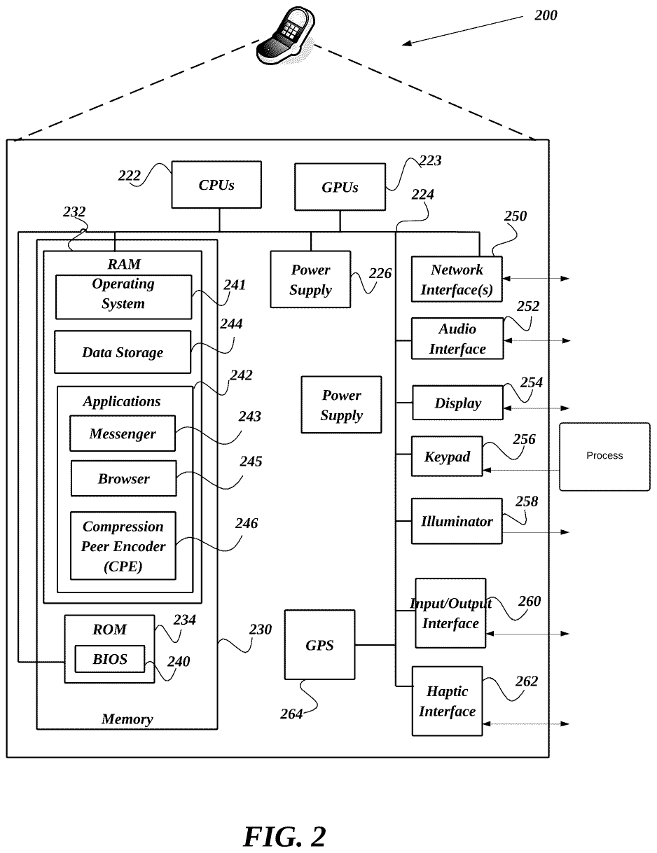

### FIG. 2. Illustrative Client Computing Device

FIG. 2 provides a more detailed view of a client computing device which in some embodiments of the invention may host the invention in whole or in part according to that embodiment. It comprises one or many central processing units (CPUs) and graphics processing units (GPUs), memory (including RAM and ROM), a power supply, network interfaces, an audio interface, a display, a keypad, an illuminator, an input/output interface, a haptic interface, and an optional GPS receiver. These components are standard in modern computing devices and enable interaction with the user and communication over the network. The memory stores an operating system and applications, including a Compression Peer Encoder (CPE). The CPE is responsible for executing the PPC algorithm and participating in distributed computations. The other components of the client device facilitate user interaction and data exchange with the experiment service and CCC server.

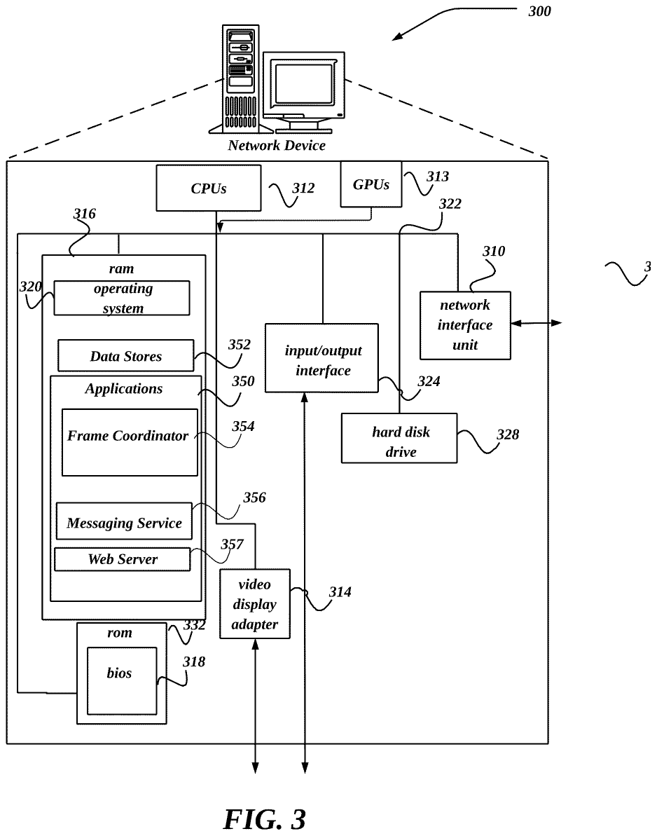

### FIG. 3. Illustrative Network Device

FIG. 3 illustrates a network device 300, which can represent the CCC server 116. It includes a processing unit 312, memory (RAM 316, ROM 332, and hard disk drive 328), a network interface 310, and a video display adapter 314. The memory stores an operating system 320, data stores 352, and applications 350.

Among the applications is a Frame Coordinator 354. This component manages the distribution of computational tasks among the client devices. It can distribute initial simulation data, collect results from client devices, and ensure consistency across the distributed computation. The network interface 310 allows the CCC server to communicate with the client devices and the physics service. Other applications, such as web server 357 and messaging server 356, can be used for user interaction and data exchange. In some embodiments, the CCC server can be implemented as a cloud-based service, with the network device 300 representing a virtual machine or container instance. In others, the Client Computing Device 101-104 can host the CCC server in whole or in part.

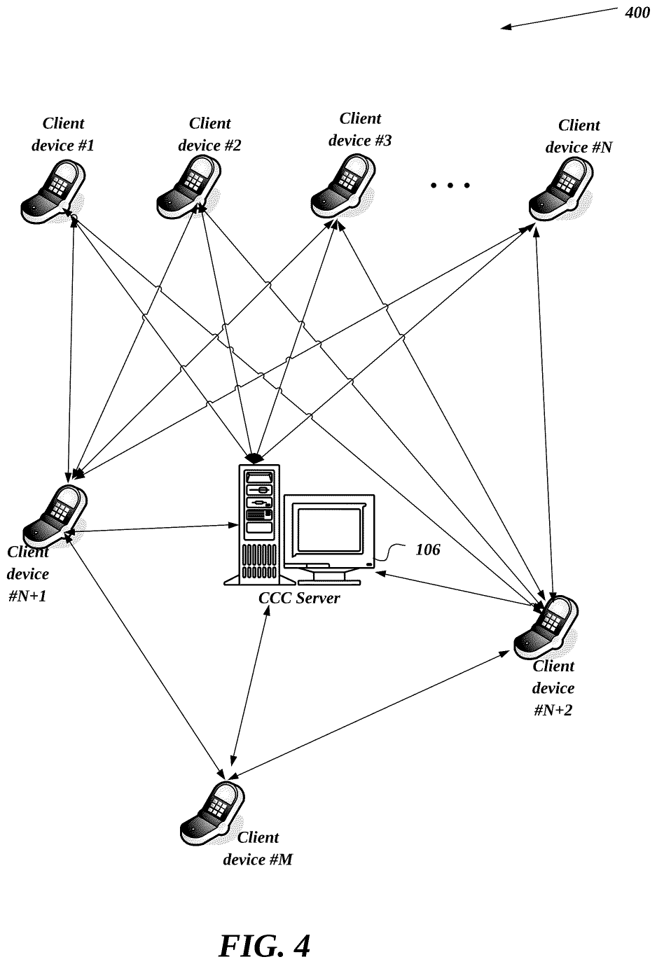

### FIG. 4. Distributed Calculation Environment

FIG. 4 shows a system 400 illustrating a distributed calculation such as a peer-to-peer, decentralized, or mediated clustered networking environment. Client devices 1-N, N+1, N+2, and M interact with the CCC server 106. The CCC server can distribute portions of a physics simulation (e.g., initial conditions, frame hierarchies) to the client devices. Each client device then performs computations on its assigned portion using the FPCL.

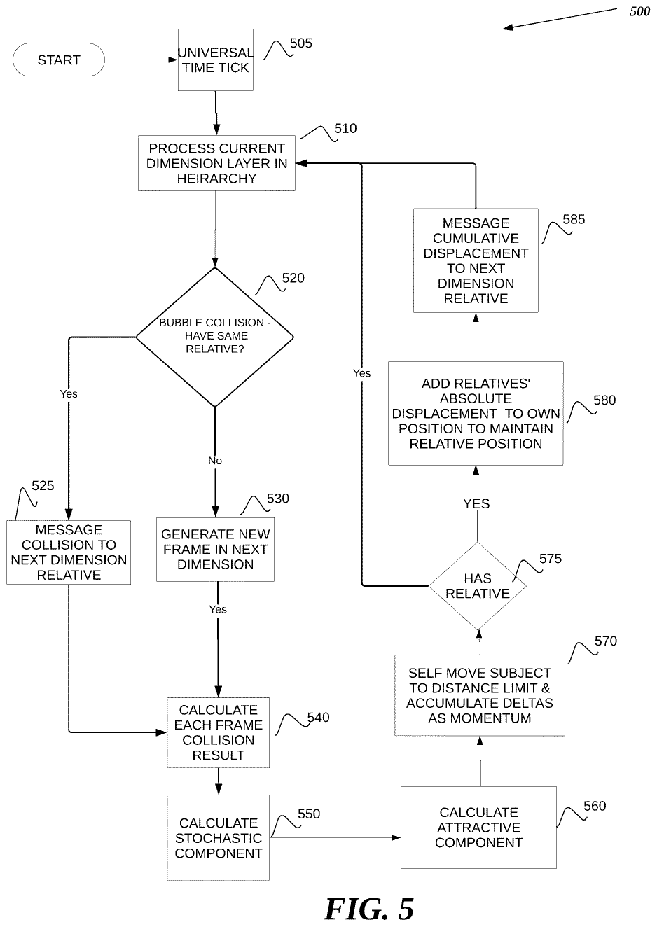

### FIG. 5. Single-threaded, Single-processor Pass of the PPC Algorithm

FIG. 5 details a single-threaded, single-processor pass of the FPCL algorithm (process 500), corresponding to an exemplary function pass which computes the state of the system after one universal time step (herein tick). This description focuses on a bottom-up approach, starting from individual quanta and building up to parent frames. It's important to note that this is an exemplary approach, and a top-down implementation is equally valid due to the inherent consistency enforced by the FPCL.

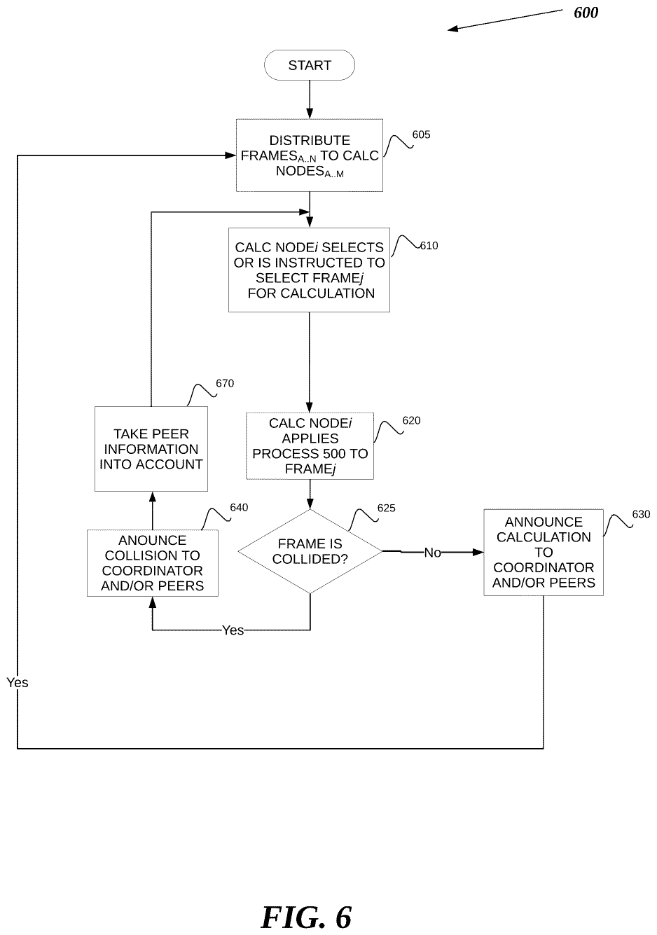

### FIG. 6. Distributed Computation in a Compression Environment

FIG. 6 illustrates a logical flow diagram of an overview process for distributed computation of the PPC algorithm within a distributed calculation environment. The process can be deployed within the CCC server and/or client devices.

### DETAILED DESCRIPTION OF THE INVENTION

The present invention will be described more fully with reference to the accompanying drawings, which illustrate specific embodiments. This invention may be embodied in many different forms and should not be construed as limited to the embodiments set forth herein; rather, these embodiments are provided so that this disclosure will be thorough and complete, and will fully convey the scope of the invention to those skilled in the art. The present invention may be embodied as methods, systems, or devices. It may take the form of an entirely hardware embodiment, an entirely software embodiment, or an embodiment combining software and hardware aspects, or embodiments on one device or distributed across many.

Throughout the specification and claims, the following terms take the meanings explicitly associated herein, unless the context clearly dictates otherwise. The phrase “in one embodiment” as used herein does not necessarily refer to the same embodiment, though it may. Furthermore, the phrase “in another embodiment” as used herein does not necessarily refer to a different embodiment, although it may. Various embodiments of the invention may be readily combined. The term “or” is an inclusive “or” operator and is equivalent to the term “and/or,” unless the context clearly dictates otherwise. The term “based on” is not exclusive and allows for being based on additional factors not described. The terms “a,” “an,” and “the” include plural references. The term “in” includes “in” and “on.”

The present invention introduces a novel Physics Computation Language (PCL), referred to as a “Fractal Physics Computation Language” (FPCL), and associated system architecture for predicting the states of physical systems, diverging from traditional calculus-based methods. This FPCL leverages principles of fractal compression, Numerical Linear Algebra (NLA) transforms, and recursive computations to achieve efficient and accurate simulations. The core concept involves representing the physical system as a hierarchy of interacting frames, where each frame encapsulates a portion of the system's state. Convergence in this framework is achieved not through iterative approximation of continuous ODE equations, but by enforcing specific relationships between frames at different levels of the hierarchy. NLA transforms and recursive steps ensure that key physical properties, such as Lorentz invariance, are preserved at every level. This approach eliminates the need for error term comparisons with differential equations, as the algorithm inherently maintains consistency—for example, a consistent calculation is one in which the end result is the same regardless of whether the computation proceeds top-down or bottom-up hierarchical traversal.

In contrast to fractal image compression which reverse engineers an image for efficient storage of a present state, the novel algorithm presented here focuses on the efficient forward prediction of future states given information about a present state. FPCLs differ fundamentally from “Fractal Reverse Engineering Compression” (FREC) techniques which, by definition, operate to reverse engineer and compress a present state such as a 2D image or 3D video. Additionally, where convergence in FREC is generally determined by some notion of “distance” between the original image/video and the compressed representation, convergence in FPCLs is determined when all the frames in a traversal path of the hierarchical representation of the universe (or some discrete subset of the universe which can be calculated independently) have been computed for desired properties such as displacement, mass, momentum, or energy.

### General Operations

Operations of the FPCL in both exemplary embodiments on a single computing device and in a distributed computation framework will now be described with reference to FIGS. 4-6. These figures illustrate the interaction between the client devices and the CCC server in performing physics simulations. FIG. 4 shows a system 400 illustrating the distributed computation aspect of the invention. Client devices 1−N, N+1, N+2, and M interact with the CCC server 106. The CCC server can distribute portions of a physics simulation (e.g., initial conditions, frame hierarchies) to the client devices. Each client device then performs computations on its assigned portion using the FPCL. The client devices can communicate with each other directly (peer-to-peer) or through the CCC server to exchange intermediate results and ensure consistency. The CCC server can also collect the final results from the client devices and combine them to produce the complete simulation output. This distributed approach allows for efficient parallelization of the computation, leveraging the computational resources of multiple devices. The system also supports dynamic load balancing, adapting to the availability and capabilities of the client devices.

FIG. 5 details a single-threaded, single-processor pass of the FPCL algorithm (process 500), corresponding to an exemplary function pass which computes the state of the system after one universal time step (herein tick). This description focuses on a bottom-up approach, starting from individual quanta and building up to parent frames. It's important to note that this bottom-up approach is an exemplary one, and a top-down implementation is equally valid due to the inherent consistency enforced by the FPCL.

Before proceeding, we define several key terms used in the description of the FPCL:
1. Universal Grid (sometimes referred to as “Absolute Space”): The universal grid is a discrete representation of space having a number of dimensions d exceeding 0 (e.g. a one-dimensional line, a two-dimensional plane, etc.), where for illustrative purposes herein each cell corresponds to a pixel representing the fundamental quantum of space. The grid is used to discretize the physical system and provide a common reference frame for all calculations. Absolute space is therefore measurable in absolute units of distance.
2. Frame: A frame represents a discrete portion of the physical system at a specific level of detail. It encapsulates properties such as position, velocity, mass, and other relevant physical quantities. Frames can be nested hierarchically, with larger frames having smaller child frames (referred to as quanta). Frames which are direct descendents or ancestors of each other are herein sometimes referred to as “relations.”
3. Quantum: Because recursive algorithms can cause syntactic confusion such as referring to frames which are children of other frames and so on, in the context of the FPCL, a quantum is a syntactic convenience for referring to a frame child.
4. Dimension: A Dimension in the FPCL corresponds to a level in the hierarchy where frames at that Dimension have like sizes. For illustrative purposes, in one embodiment, on a 2D Universal Grid, Dimension 0 represents a 1 pixel by 1 pixel leaf quantum, a Dimension 1 frame might be 2×2, a Dimension 2 frame might be 4×4, etc., where higher Dimensions represent increasingly larger scales, formed by combining frames from lower Dimensions.
5. Universal Tick (sometimes called “Grid Time” or “Absolute Time”): A tick represents a discrete unit of time in the simulation. Each universal tick advances the simulation by one time step.

In principle, it will be helpful to understand the FPCL algorithm as a recursive process that constructs a hierarchy of frames representing a physical system and from which the repeated application of the algorithm results in emergent physics behaviors that are consistent at every scale of the computation and respect both Lorentz invariance and ergodicity. It is understood by those in the art that embodiments using tree data structures and recursive algorithms can equally be represented using other structures and calculation progressions and the embodiment herein is exemplary and non-limiting in this regard. The FPCL algorithm is designed to predict the future state of the system by applying NLA transforms and recursive calculations to the current state. The algorithm enforces the following important constraints including but not limited to:
traversal of the hierarchy such that the next state of the system is computed by calculating the next state of the constituent frames
single occupancy of cells at the lowest level of the hierarchy, ensuring that no two leaf quanta can occupy the same location in space.
an attractive force applied to each frame, ensuring that quanta are drawn towards the center of their parent frame such that during any universal tick.
stochastic movement each frame, introducing randomness and entropy into the system.
a relative speed limit−that is, there is a relative displacement limit on a frame (tick unit of time=max unit of fundamental grid distance of displacement) as between parent and child frames, ensuring both that in the special case of two intra-frame observers there is a maximum perceived speed of light and in the general case across all frames.

The reader will appreciate that the recursive application of the FPCL algorithm does not limit the absolute distance which a quantum can travel in a single universal tick to 1 unit of absolute distance. The absolute distance traveled by a quantum in a single universal tick is a function of the number of times the quantum has been nested in the hierarchy. For example, a quantum nested 3 levels deep in the hierarchy will travel a maximum of 3 units of absolute distance in a single universal tick. This is a key feature of the FPCL algorithm which allows for the emergent behavior of Lorentz invariance.

Process 500, in different embodiments, may be deployed in whole or in parts on environments 100, 200, 300, or 400 as dictated by the needs of the embodiment. Process 500 begins at block 505 with processing of calculations of state related to the next universal time tick. Processing starts at block 510, where the previous state of the physical system is received from the last pass or from an external user or system. We shall refer to this initial state as the “Experiment” to be computed. This state is represented as a collection of frames at the lowest level of the hierarchy (e.g., individual quanta). In a typical physics simulation, this initial state may represent the positions, velocities, and other properties of the fundamental constituents of the system. For example, in a double-slit experiment the external system might simulate a quantum gun that places new quanta onto the lowest level of the frame hierarchy grid, or place a large object detector for collisions which produce interference patterns. The algorithm enforces single occupancy such that two quanta cannot occupy the same location in space (referred to as a “pixel” for simplicity, though the concept generalizes to higher Dimensions). Any attempt to violate single occupancy is considered a collision. In one embodiment, newly introduced quanta, or collisions, resulting from actions taken in external pre-tick hook functions, are handled before continuing.

At block 510, the algorithm checks for collisions at the fundamental level (Dimension 0) by inserting the quanta into a hierarchy which is represented in an exemplary spacial data structure, herein called the FrameTree. The FrameTree efficiently detects collisions by identifying quanta that attempt to occupy the same pixel. Any collided quanta are marked for further processing in subsequent steps of the algorithm. This corresponds to enforcing the single occupancy constraint.

Block 520 represents the hierarchical frame construction. If the collided quanta have existing parents, then those parents are messaged about the collision because they are also collided. In the exemplary implementation, the generation of a frame parent occurs in block 530 as a consequence of a collision—hence there is a minimum frame occupancy of two at frame generation, and we could say that the two quanta that collided became “entangled.” For instance, two colliding, adjacent quanta in Dimension 0 can be grouped to create a parent frame in Dimension 1. This grouping, efficiently implemented using FrameTrees or other spatial data structures, establishes parent-child relationships between frames at adjacent Dimensions.

Block 540 represents the calculation attendant to the collision. A variety of collision logic may be applied so long as it is consistent with the FPCL constraints. The invention enables modular collision logic so long as the logic mathematically consistent in its transforms. For example, for speed purposes one embodiment may use “pixel perfect” collision detection as it is known in the art and another may use probabilistic collisions where accuracy below a certain threshold may be sacrificed. Yet other embodiments may use both pixel perfect and probabilistic at different levels of the hierarchy will enforcing that the average probabilistic collision results converge to an approximately the same result as the pixel perfect within acceptable error tolerances for that level of the hierarchy. Exploration of different collision logic may comply with new real-world experimental results. The most basic collision applied in one embodiment is to enforce the no-double occupancy rule such that one or both of the collided quanta must undo all or part of a move.

More complex collision logic might involve the creation of new quanta or the destruction of quanta. The collision logic may be applied recursively to the parent frames as well.

Block 550 applies the stochastic movement transform. This transform, implemented via random matrices or functions, is applied to each frame and introduces emergent entropy into the system. It represents one in a series of transforms that produce the emergent physics behavior of the system. These transforms are a configurable aspect of the FPCL, allowing flexibility in simulating various physical phenomena.

Block 560 represents the application of the attractive force transform. This transform is applied to each frame, drawing the quanta towards the center of their parent frame by a unit of absolute distance per universal tick. The operation of other steps and paths in the process ensures the attractive force is applied recursively to all levels of the hierarchy and is cumulative to the nesting level but relatively limited to a unit of absolute distance per universal tick as between parent and child.

Block 570 represents the application of the displacement limit transform. This transform enforces a maximum relative displacement between quanta within a frame and between parent and child frames. For example, if the sum of the stochastic move in block 550 and attractive component in block 560 would exceed 1 unit of absolute distance, then the remainder is accumulated into a variable such as a velocity vector of the frame, but the absolute displacement magnitude is limited to 1 absolute unit of distance. The operation of other steps and paths in the process ensures the speed limit is applied recursively to all levels of the hierarchy.

Block 580 moves the quantum relative to its parent frame, ensuring that, apart from the quantum's calculated move, it stays in the same position relative to its parent frame. The operation of block 585 and other paths in the process ensures the recursive relative movement to all levels of the hierarchy such that all frames in the hierarchy maintain relative position to all others except for their own calculated move consisting of the stochastic component in block 550 and attractive component in block 560 and other transformations as necessary to the embodiment.

The recursion continues via block 585, passing back to block 510, until the entire hierarchy has been processed. The process is repeated for each universal tick, with the state of the system evolving over time. The FPCL algorithm enforces the constraints of single occupancy, attractive force, stochastic movement, and displacement limit at every level of the hierarchy.

FIG. 6 illustrates a logical flow diagram of an overview process 600 for distributed computation of the FPCL algorithm within a distributed calculation environment. Process 600 can be deployed within the CCC server 116 (FIGS. 1 and 3) and/or client devices 101-104 (FIG. 4).

The process begins at block 605, where portions of the physics simulation, represented as frames A . . . N, are distributed to available calculation nodes (client devices) A . . . M. Each client device may receive a subset of frames, and the distribution strategy can be adapted based on factors such as network topology, node capabilities, and desired load balancing. Note that under the exemplary implementation each device effectively receives a copy of a subset of the state to be calculated.

At block 610, each calculation node A . . . M selects, or is instructed by the CCC server to select, a specific frame j for processing. The selection process can be randomized or based on a predetermined assignment strategy.

Block 620 represents the core computation step, where the selected calculation node applies the relevant assigned portions of process 500 (FIG. 5) to frame j. This may include executing the FPCL algorithm on the assigned frame, updating its state based on internal interactions and external forces.

At block 625, the calculation node considers information received from its peers. This information may include updates on frame states, notifications of collisions, or other relevant data that can influence the local computation. The specific mechanisms for peer communication and data exchange will depend on the underlying swarm architecture and communication protocols.

Block 630 represents the communication step where the calculation node announces the results of its computation to the CCC server and/or its peers. This announcement may include the updated state of frame j, any detected collisions, or other relevant information.

If, during the computation in block 620, a collision is detected within frame j (decision block 640), the calculation node announces this collision to the CCC server and/or its peers (block 650). This information is crucial for maintaining consistency across the distributed computation, as collisions may affect frames processed by other nodes. The exemplary embodiment uses a top-down recursion which will result in the same calculation state as the previously illustrated and described bottom-up recursion so under this exemplary embodiment collision information is ignored by other nodes.

Block 660 represents a check for overall convergence or termination criteria. The criteria may include a minimum number of reporting client devices or levels computed in the hierarchy, a target accuracy level, or other application-specific conditions. If the criteria are met, the process terminates. Otherwise, the process loops back to block 610, and the calculation nodes continue processing frames until convergence or termination.

At block 670 integration of information received from peer nodes occurs. This information, which may include frame updates or collision notifications, is used to refine the local computation and ensure consistency across the distributed simulation.

At decision block 640, a check is performed to determine if any collisions have occurred during the processing of frame j. If a collision is detected, the calculation node proceeds to block 650 and this announcement allows other nodes to be aware of the collision and adjust their computations accordingly.

Block 660 represents the decision point where the system checks for termination criteria primarily as to the full recursive traversal of the hierarchy being completed to the desired level. These criteria can be defined based on factors such as the number of iterations, desired accuracy, or a predetermined time limit. If the criteria are met, the process terminates. Otherwise, the process loops back to block 610 to select the next frame for processing. The loop continues until termination conditions are satisfied.

It will be understood that each block of the flowchart illustration, and combinations of blocks in the flowchart illustration, can be implemented by computer program instructions. These program instructions may be provided to a processor to produce a machine. The computer program instructions may also cause at least some of the operational steps shown in the blocks of the flowchart to be performed in parallel. Moreover, some of the steps may also be performed across more than one processor, such as might arise in a multi-processor computer system. In addition, one or more blocks or combinations of blocks in the flowchart illustration may also be performed concurrently with other blocks or combinations of blocks, or even in a different sequence than illustrated without departing from the scope or spirit of the invention. Accordingly, blocks of the flowchart illustration support combinations of means for performing the specified actions, combinations of steps for performing the specified actions and program instruction means for performing the specified actions. It will also be understood that each block of the flowchart illustration, and combinations of blocks in the flowchart illustration, can be implemented by special purpose hardware based systems, which perform the specified actions or steps, or combinations of special purpose hardware and computer instructions.

What is claimed as new and desired to be protected by Letters Patent of the United States is:

1. A method for simulating a physical system on a computing device having at least one processor, the method comprising:
receiving a representation of the physical system, the representation comprising a set of frames wherein each frame comprises:
a position within a universal grid; and
at least one leaf frame residing at a lowest level in the hierarchy of the simulation;
advancing the simulation on a universal tick by tick basis;
on each universal tick traversing the hierarchy of frames, level by level calculating frames by performing the following operations:
incorporating information on displacement of the previous frame relation, if any, in the traversal hierarchy into the current frame such that the current frame is displaced by the same amount on the universal grid as the previous frame relation prior to the current frame calculating its own additional displacement,
detecting collisions between frames at each level, and, for each collided frame pair:
ensuring their leaf quanta in the hierarchy are not in the same position in the universal grid; and,
mediating leaf quanta collisions by moving one or the other leaf quanta to a non-collided position on the universal grid;
applying a stochastic movement transform to displace each frame within the universal grid;
applying an attractive force transform to displace the quanta children of each frame towards a point in their parent frame;
applying a limit to the displacement attributable to the sum of the frame's stochastic movement transform and attractive force transform to be a maximum magnitude of absolute distance measured on the universal grid and accumulating any unmoved displacement into a an accumulator variable impacting future move transforms or likelihoods of displacement;
calculating the new position of the frame on the universal grid based on the applied transforms and displacement limit;
re-calculating aggregate properties of the frame based on the properties of its predecessor frame relations in the traversal order;
exposing the recalculated properties of the frame to the next level of the hierarchy in the traversal order;
updating the representation of the physical system with the new position and other properties of the frame.

2. The method of claim 1, wherein the stochastic movement transform is based on a random matrix.

3. The method of claim 1, wherein the attractive force transform displaces the frame towards the center of its parent frame by a fixed amount per universal time step.

4. The method of claim 1, wherein the maximum relative displacement limit restricts the displacement of a frame relative to its parent frame per universal time step.

5. The method of claim 1, wherein the detecting collisions operation identifies collisions by comparing positions of the child frames of a given frame in the hierarchy using different means such as binary searches or quadtrees.

6. The method of claim 1, wherein creating a parent frame is performed if a detected collision occurs, associating the collided child frames with the new parent frame one level higher in the frame hierarchy.

7. The method of claim 1, further comprising distributing the calculations of each frame amongst computing threads.

8. The method of claim 1, further comprising distributing the calculations of each frame amongst GPUs.

9. A network device, comprising:
a transceiver to send and receive data over a network; and
a processor that is operative on the received data to perform actions, including:
distributing a plurality of frames, representing portions of a physical system simulation (the “Experiment”), to a plurality of different calculation nodes A . . . M (e.g. client devices, peer-to-peer configured or otherwise);
wherein each calculation node A . . . M is configured to select or be instructed to select at least one frame j from the plurality of frames, and to perform at least one block in one pass of a Fractal Physics Computation Language (FPCL) algorithm (process 500) upon the selected at least one frame j;
receiving at least one resulting output result for frame j from a calculation node A . . . M, the at least one resulting output result generated by the calculation node performing at least one one block of one pass of the FPCL algorithm on the at least one selected frame j;
if at least one resulting output result indicates that a termination threshold is unsatisfied, then sending the resulting output to another one of the calculation nodes to perform at least one block of one pass of the FPCL algorithm upon the resulting output frame; and
if the received at least one resulting output frame indicates that the termination threshold is satisfied, then sending the resulting output frame to each of the other calculation nodes to replace the corresponding selected frame j in the Experiment.

10. A method of performing fractal-based physics simulation in a distributed computing environment, the method comprising:
transmitting, to each of a plurality of calculation nodes A . . . M, a plurality of frames representing portions of a physical system (the “Experiment”);
receiving, at a network device, at least one frame generated by performing at least one pass of an FPCL algorithm (process 500) upon the plurality of frames at one of the plurality of calculation nodes; and
analyzing, at the network device, the received frame to determine whether it satisfies a termination threshold.

11. The system of claim 8, wherein each of the calculation nodes A . . . M applies a different set of FPCL parameters from the others.

12. The method of claim 9, wherein each of the calculation nodes A . . . M applies a different set of FPCL parameters from the others.

13. The method of claim 9, further comprising: recursively applying the FPCL algorithm to the received frame until the termination threshold is satisfied.

14. A system for fractal-based physics simulation, comprising:
a plurality of calculation nodes A. M, each configured to execute an FPCL algorithm (process 500) on a portion of a physical system simulation; and
a network device configured to distribute portions of the physical system simulation to the calculation nodes and to collect and analyze resulting output frames from the calculation nodes.
